(19) United States
(12) Patent Application Publication
(10) Pub. No.: US 2008/0003718 A1
(43) Pub. Date: Jan. 3, 2008

(54) Singulation Process for Block-Molded Packages

(76) Inventors: Erwin Remoblas Estepa, Baguio City (PH); Ronaldo Marasigan Arguelles, Baguio City (PH); Jesus Bajo Bautista, Baguio City (PH); Joey G. Piamonte, Baguio City (PH)

Correspondence Address: TEXAS INSTRUMENTS INCORPORATED, P O BOX 655474, M/S 3999, DALLAS, TX, 75265, US

(21) Appl. No.: 11/428,079

(22) Filed: Jun. 30, 2006

(51) Int. Cl. H01L 21/00

(52) U.S. Cl. 438/113

(57) ABSTRACT

Methods are disclosed for singulating block-molded IC packages. The methods of the invention include steps for making a partial cut in a block-molded semiconductor array, the partial cut defining the perimeter of an IC package and extending partially through the thickness of the array material. In a subsequent step, a final cut is made in alignment with the partial cut at the perimeter of the package such that the package is severed from adjacent material. Various embodiments of the invention are disclosed, including methods for making a plurality of partial cuts prior to making the final cut severing the package from the array, making cuts approaching from the same surface of the array, and making cuts approaching from opposing surfaces of the array. The partial cutting steps are used to prevent array warpage and facilitate hold-down during ball attach and/or singulation processes.

### TECHNICAL FIELD

The invention relates to electronic semiconductor devices and manufacturing. More particularly, the invention relates to methods for the manufacture of packaged semiconductor devices and to processes for singulating individually packaged chips from block-molded semiconductor arrays containing multiple chips.

### BACKGROUND OF THE INVENTION

Semiconductor devices are constructed from a semiconductor material wafer through a process that includes a number of deposition, masking, diffusion, etching, implanting, and other steps. Usually, many individual devices are constructed on the same wafer. When the devices are separated into individual rectangular units, each takes the form of an integrated circuit die or chip. In order to connect a chip with other circuitry, it is common to mount it on a leadframe or on a multi-chip substrate that is surrounded by a number of contact connections. For convenience, metal leadframes and silicon substrates are referred to in general using the term “substrate” except as otherwise noted for pointing out metal leadframes in particular. Each chip has bond pads that are then individually connected in a wire-bonding operation to the substrate contact connections using extremely fine wires. The assemblies are completed by encapsulating them in molded resin, plastic or ceramic packages that provide protection from hostile environments and yet enable electrical interconnection between the integrated circuit chip and an outside assembly such as a printed circuit board (PCB) or motherboard. In general, the elements of such a package include a substrate, an integrated circuit chip, bonding material to attach the integrated circuit chip to the substrate, bond wires which electrically connect pads on the integrated circuit chip to individual leads of the substrate, and a hard encapsulant material which covers the other components and forms the exterior of the package.

For purposes of high-volume, low-cost production of IC packages, one current industry practice is to prepare, usually through a process of etching and/or stamping, a thin sheet of metal to form a panel or strip which defines multiple leadframes arranged in one or more arrays. Multi-chip arrays may also be formed of semiconductor wafer material. In a typical chip package manufacturing process, the integrated circuit chips are mounted and wire-bonded to respective locations of the substrates, with the encapsulant material then applied to the strip or array so as to collectively encapsulate all of the integrated circuit chips, bond wires, and all or portions of each of the substrates. “Block-molded” semiconductor packages, wherein numerous chips on a strip or array are encapsulated within a single molded body, are thus fabricated. Subsequent to the curing of the encapsulant, the substrates and their associated chips and leads are then cut apart or singulated for purposes of producing the individual chip packages. One common technique by which singulation is typically accomplished is a saw singulation process. In this process, the array of block molded devices is held down while a saw blade is advanced along “saw streets” which extend in prescribed patterns between the block-mold packaged chips as required to facilitate the separation of the packaged chips from one another for individual use.

Progress in integrated circuit technology continues to lead to higher and higher levels of circuit integration. This is a result of a relentless drive toward higher performance, lower cost, increased miniaturization of components, and greater packaging density. These attributes place higher demands on the saw singulation processes used to separate the individual semiconductor packages. Saw singulation technologies are efficient and well developed. However, there are significant problems in the present state of the art. For example, block-molded arrays of chips sometimes warp due to internal mechanical stresses. Warpage can occur in the “corners up” direction, “corners down” or in a combination of directions. This warpage can cause difficulties for saw singulation and ball attach processes. During singulation and ball attachment, warpage of the block-molded package arrays can result in the vacuum chuck, or other device used to secure the block-molded array for cutting, losing its ability to hold down the array. This can lead to the movement of the array during sawing and/or to the loss of singulated packages after sawing. In current manufacturing processes, the loss of vacuum resulting from warpage requires the immediate interruption of singulation so that the array can be re-secured. Such interruptions are inefficient and costly. Warped arrays are also less suitable for ball attachment due to their non-planar surface, which may inhibit receiving balls arranged in a planar grid. Solutions to these problems have been sought but prior developments have neither taught nor suggested complete solutions, thus new solutions to addressing these problems would be useful and advantageous contributions to the arts.

### SUMMARY OF THE INVENTION

In carrying out the principles of the present invention, in accordance with preferred embodiments thereof, singulation methods are disclosed for use with block-molded semiconductor device packaging processes.

According to one aspect of the invention, a method for singulating block-molded IC packages includes steps for making a partial cut in a block-molded semiconductor package array. The partial cut is made to coincide with the perimeter of an individual package and extends partially through the thickness of the array material. A further step is included for making a final cut aligned with the partial cut at the perimeter of the package such that the package is severed from adjacent material.

According to another aspect of the invention, embodiments of the methods of the invention further include steps for making additional intermediate partial cuts before making the final cut.

According to yet another aspect of the invention, methods are disclosed for fabricating semiconductor chip packages. The methods include steps for providing a semiconductor substrate or metal leadframe array for multiple packages that are to be singulated with respective predetermined chip locations. In further steps, semiconductor chips are affixed to array chip locations and encapsulated using block-molding techniques to encompass the affixed chips. The block-molded array is cut to singulate chip packages using a cut partially through the array assembly and defining the boundaries of an individual chip package followed by a final cut, providing a singular package severed from the array.

According to still another aspect of the invention, methods embodying the invention include cutting steps making use of sawing processes.

The invention has advantages including but not limited to one or more of the following: reducing stresses on packages during singulation; reducing warpage of packaged devices during singulation; reducing manufacturing costs due to reductions in interruptions in the singulation process and reduced damage to packages or packaged chips. The features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 (prior art) is a top view representative of a strip containing several arrays of numerous block-molded semiconductor devices prior to singulation showing an overview of an example of a context in which methods embodying the invention may be practiced;

FIG. 2 (prior art) is a side view of the strip of FIG. 1 containing several arrays of numerous block-molded semiconductor devices prior to ball attach and singulation shown for the purpose of illustrating an example of warpage in a context in which methods embodying the invention may be practiced;

FIG. 3A is a partial side view of an array of joined block-molded semiconductor devices illustrating an example of steps in the methods of preferred embodiments of the invention;

FIG. 3B is a partial side view of the array of FIG. 3A containing block-molded semiconductor devices illustrating an example of steps in the methods of preferred embodiments of the invention;

FIG. 3C is a partial side view of the block-molded semiconductor devices of FIGS. 3A and 3B illustrating an example of further steps in the methods of preferred embodiments of the invention;

FIG. 4A is a partial side view of an array of joined block-molded semiconductor devices illustrating an example of steps in the methods of alternative preferred embodiments of the invention;

FIG. 4B is a partial side view of the array of FIG. 4A containing block-molded semiconductor devices illustrating an example of further steps in the methods of preferred embodiments of the invention;

FIG. 4C is a partial side view of the block-molded semiconductor devices of FIGS. 4A and 4B illustrating an example of further steps in the methods of preferred embodiments of the invention;

FIG. 5 is a partial side view of an example of alternative steps in representative embodiments of block-molded semiconductor devices pursuant to methods of the invention;

FIG. 6 is a simplified process flow diagram providing an alternative overview of a method for fabricating integrated circuit chip packages according to the invention; and

FIG. 7 is a simplified process flow diagram providing an overview of an alternative embodiment of a method for fabricating integrated circuit chip packages according to the invention.

References in the detailed description correspond to like references in the various drawings unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DESCRIPTION OF PREFERRED EMBODIMENTS

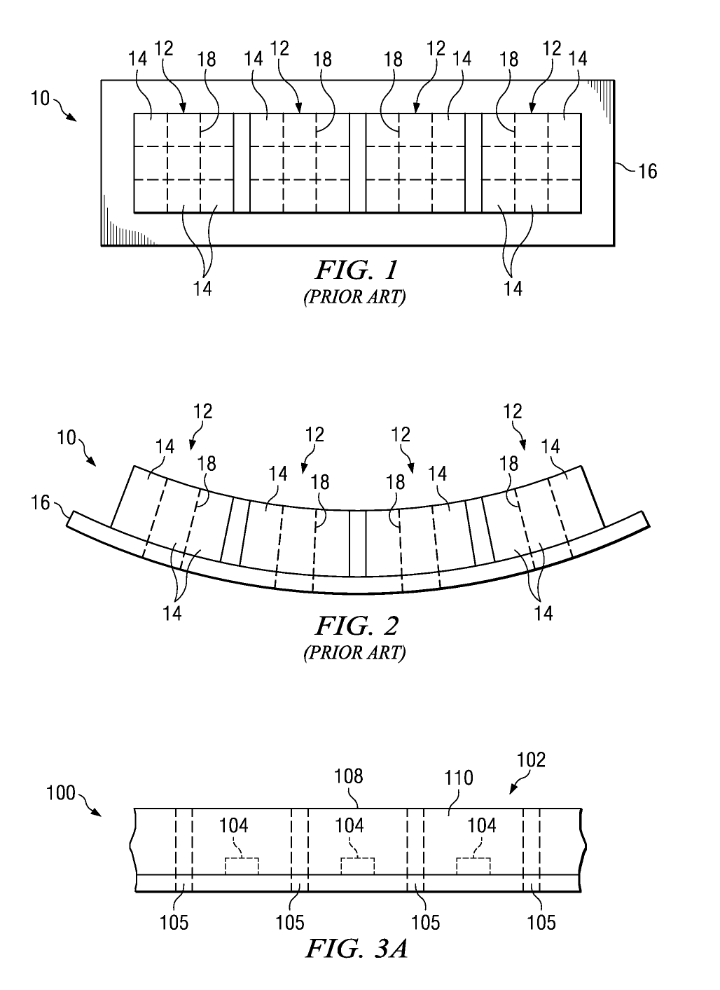

Referring initially to FIG. 1 (prior art), a top view, and FIG. 2 (prior art), a corresponding side view, the figures are representative of an arrangement 10 of arrays 12 of block-molded semiconductor device assemblies 14 prior to the singulation of the individual packages 14. In conventional fashion, semiconductor package arrays 12 are formed by block-molding, for example, on a leadframe or multilayer substrate strip 16. The individual semiconductor packages 14 that are yet to be singulated from the semiconductor package arrays 12 are typically held down by the application of a vacuum, supported on a tape, held in a jig, or otherwise secured for singulation. Conventionally, the individual packages 14 are sawn apart from one another by sawing through the assembly 10 in a single pass along saw streets 18 of sacrificial material between the individual packages 14. Often, the array 10 may become warped, as shown with some exaggeration in FIG. 2, leading to problems with singulation, ball attachment, or both.

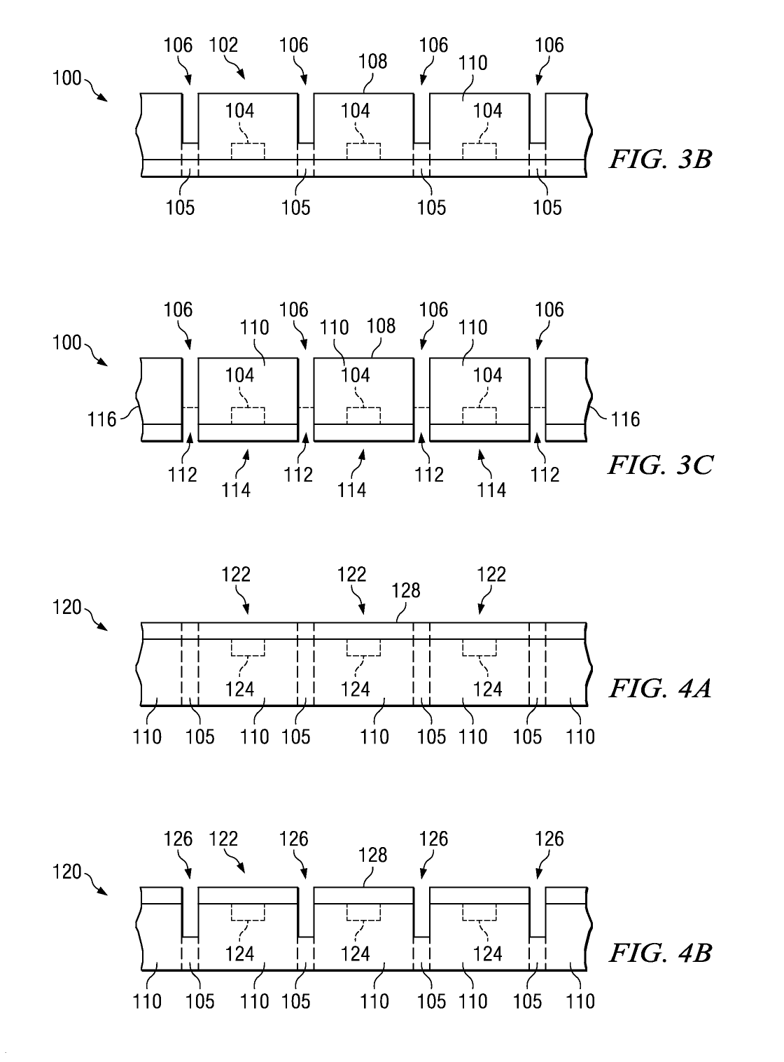

Now referring to the partial side views of FIGS. 3A-3C, a portion of a block-molded package assembly 100 is shown containing an array 102 of encapsulated ICs 104 prepared using block-molding techniques familiar to those skilled in the arts. Preferably, saw streets 105 are provided in the ordinary manner to facilitate singulation. The array 102 is held firmly in place for sawing, preferably using a vacuum chuck to force the array 102 down against a flat surface. As shown in FIG. 3B, a series of partial cuts 106 are made beginning at the outer surface 108 of the encapsulant 110. The partial cuts 106 are preferably made in a predetermined singulation pattern using conventional sawing equipment. It should be recognized that the partial cuts 106 are a departure from conventional singulation methods, in that they do not extend completely through all layers of the package assembly structure 100. Making the partial cuts reduces or eliminates warpage of the array 102 and facilitates effective securing of the array 102 by the vacuum chuck or other securing method. As can be seen in FIG. 3C, final cuts 112 are subsequently made substantially aligned with the partial cuts 106 of FIG. 3B such that the individual packages 114 are ultimately severed from one another and from any remaining material 116, such as scrap. It should be appreciated by skilled practitioners of the relevant arts that the partial cutting step may be reiterated one or more additional times intermediate to the final cutting step. It should also be understood that the partial and final cutting steps may be performed in a variety of patterns selected based on the particular application, and that the cutting steps may be performed either by repeated use of the same equipment or by using different equipment in sequence. For example, it may in some instances be advantageous to make the partial cuts and final cuts in two or more passes with the same saw blade. In other applications, it may be desirable to use different equipment for the sequence of cuts, e.g., using one saw blade for one or more partial cuts followed by another saw blade for the final cuts.

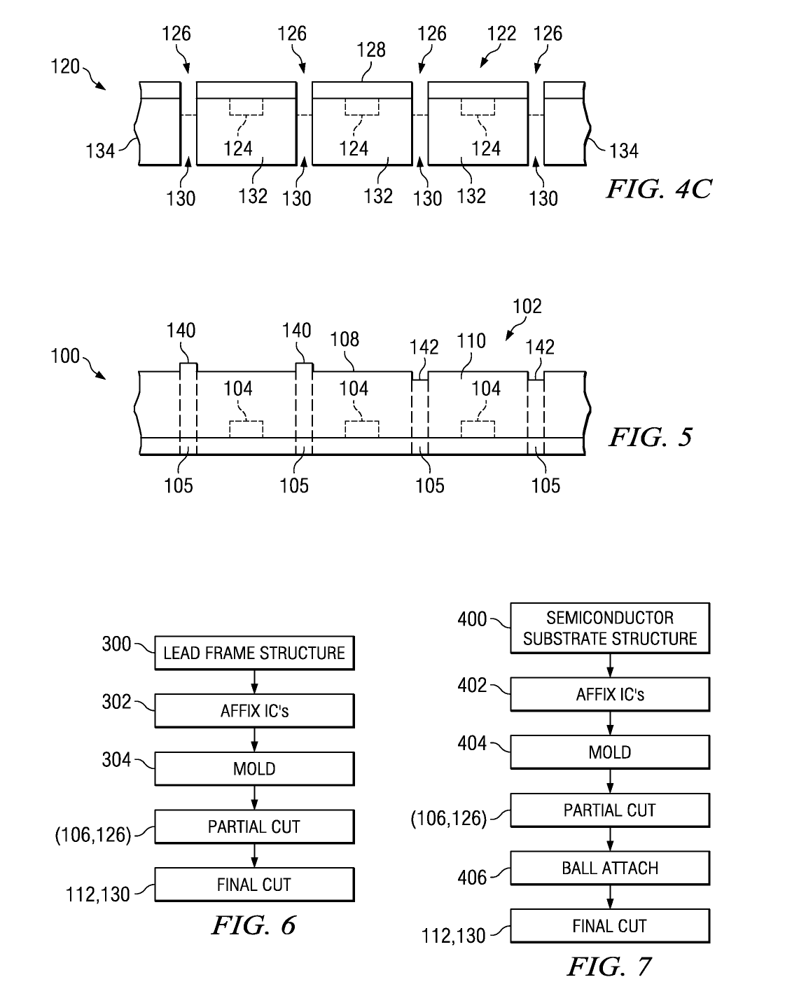

An example of one alternative embodiment of a singulation method of the invention is shown in partial side view in FIGS. 4A-4C. Referring first primarily to FIG. 4A, a portion of a block-molded package assembly 120 is shown containing an array 122 of encapsulated ICs 124. A series of partial cuts 126, shown in FIG. 4B, are made beginning at the outer surface 128 and extending part way, but not entirely, through the package assembly 120, preferably in a predetermined singulation pattern using conventional cutting equipment. The partial cuts 126 extend into, but not through, the array structure 120. As illustrated in FIG. 4C, final cuts 130 are thereafter made substantially in alignment with the partial cuts 126 of FIG. 4B such that the individual packages 132 are severed from one another, and from any additional material 134. As in the case of the above examples herein, variations in the method are possible without departure from the invention, for example, the partial cutting step may be repeated one or more additional times intermediate to the final cutting step. It should also be understood that the partial and final cutting steps may be performed by cutting tools approaching from the same or opposite surfaces of the block-molded device array.

An additional technique which may be used with the methods of the invention is to implement steps for including a cutting guide in the block-molded assembly in order to facilitate singulation. As shown in FIG. 5, cutting guides 140, 142, may be provided in the encapsulant 110 of an array 102 of suitably prepared ICs 104. The cutting guides 140, 142, are preferably formed of elevated ridges 140 or indented trenches 142 for use in guiding the cutting tool, e.g. saw, particularly for the making of the initial partial cuts, although alternative cutting guidance or techniques may also be used.

Referring now to FIG. 6, a process flow diagram of exemplary methods for fabricating leadframe packages in accordance with the present invention is shown. This example of a preferred embodiment of the invention includes a package array based on a supporting metal leadframe, such as a Quad Flat No-lead (QFN) package. The method includes providing a collective leadframe structure 300 for packages that are to be assembled thereupon and subsequently singulated with respective predetermined package shapes and sizes. The required IC chips are affixed to the leadframes at selected locations, as shown at step 302. The packages are assembled in a block with encapsulant for forming individual mold caps on the leadframes 304. The arrayed packages preferably have sufficient saw streets between them to allow for cutting. The packages are cut, preferably by sawing, using successive partial 106, 126, and final cuts 112, 130, to singulate the packages, preferably reducing the dimensions of the packages to the respective predetermined package sizes.

As depicted in the simplified process flow diagram of FIG. 7, a process flow diagram of exemplary methods for fabricating BGA packages in accordance with the present invention is shown. The method includes providing a collective substrate structure 400 for packages that are to be assembled thereupon and subsequently singulated with respective predetermined package shapes and sizes. The required IC chips are affixed to the appropriate substrate locations, as shown at step 402. The packages are assembled in a block with encapsulant for forming individual mold caps over the chips 404. The arrayed packages preferably have sufficient saw streets between them to allow for cutting. The packages are cut, preferably by sawing successive partial cuts 106, 126. Solder balls are preferably attached to the package 406 for use in further employment of the packaged device in electronic apparatus. Final cuts 112, 130, ultimately singulate the packages, preferably reducing the dimensions of the packages to the respective predetermined package sizes. It should be noted that additional steps, or variations in the order of the steps, may be implemented without departure from the invention. For example, ball attachment may be performed before or subsequent to the partial cutting step(s). The presence of the partial cuts reduces or eliminates warpage, providing a flat surface suited for receiving solder balls.

The resulting package structure is an economical high integrity package that benefits from the advantages of block-mold package formation and the advantages of saw singulation while eliminating or reducing one or more of the disadvantages associated with warpage that can accompany traditional singulation methods. The invention may be used with conventional molding, ball attach, and singulation processes and tools, and may be adapted for manufacturing semiconductor packages in a wide of variety of dimensions and configurations. The methods of the invention provide one or more advantages including but not limited to reducing warpage of block-molded semiconductor devices during manufacturing. While the invention has been described with reference to certain illustrative embodiments, those described herein are not intended to be construed in a limiting sense. For example, variations or combinations of steps in the embodiments shown and described may be used in particular cases without departure from the invention. Various modifications and combinations of the illustrative embodiments as well as other advantages and embodiments of the invention will be apparent to persons reasonably skilled in the arts upon reference to the drawings, description, and claims.

We claim:

1. A method for singulating block-molded IC packages comprising the steps of:
securing a block-molded semiconductor array for cutting;
making a partial cut in the block-molded semiconductor array, the partial cut defining the perimeter of an IC package and extending partially through the thickness of the array material; and
making a final cut in alignment with the partial cut at the perimeter of the IC package such that the IC package is severed from adjacent material.

2. A method according to claim 1 further comprising the steps of making a plurality of partial cuts.

3. A method according to claim 1 wherein a partial cut and a final cut are made by applying a cutting tool at the same surface of the array.

4. A method according to claim 1 wherein a partial cut and a final cut are made at opposing surfaces of the array.

5. A method according to claim 1 wherein the block-molded array is secured using a vacuum force.

6. A method according to claim 1 further comprising the steps of:
forming an integral sawing guide on the block-molded array; and
utilizing the integral sawing guide in at least one cutting step.

7. A method for fabricating semiconductor chip packages, comprising:
providing a substrate array for multiple packages suitable for singulation with respective predetermined chip locations;
affixing semiconductor chips to the substrate chip locations;
block-molding encapsulant to encompass the affixed chips;
securing the array in a position for cutting; and
cutting the block-molded array to singulate chip packages therefrom, the cutting step further comprising;
making a partial cut partially through the array, the partial cut defining the boundaries of at least one individual chip package; and
making a final cut at the boundaries of the individual chip package, thereby providing a singular package.

8. A method according to claim 7 wherein the block-molded array is secured using a vacuum force.

9. A method according to claim 7 further comprising the steps of making a plurality of partial cuts.

10. A method according to claim 7 wherein at least one of the cutting steps further comprises sawing.

11. The method of claim 7 further comprising the steps of:
forming an integral cutting guide on the block-molded array; and
utilizing the integral cutting guide to assist at least one of the cutting steps.

12. The method of claim 7 further comprising the steps of:
forming an integral cutting guide comprising a raised ridge on the block-molded array; and
utilizing the integral cutting guide to assist at least one of the cutting steps.

13. The method of claim 7 further comprising the steps of:
forming an integral cutting guide comprising a trench on the block-molded array; and
utilizing the integral cutting guide to assist at least one of the cutting steps.

14. A method for fabricating semiconductor chip packages, comprising:
providing a substrate array for receiving chips, the array configured such that the received chips may be singulated to define respective individual packages;
encapsulating the arrayed chips by block-molding; and
saw singulating the block-molded array to singulate individual packages therefrom, the saw singulation step further comprising;
securing the array in a position for sawing;
making a partial cut in the block-molded array, the partial cut defining the perimeters of a plurality of packages and extending partially through the thickness of the array; and
making a final cut in alignment with the partial cut at the perimeter of the packages such that packages are severed from adjacent material.

15. A method according to claim 14 wherein the block-molded array is secured using a vacuum force.

16. A method according to claim 14 further comprising the steps of making a plurality of partial cuts.

17. The method of claim 14 further comprising the steps of:
forming an integral sawing guide on the block-molded array; and
utilizing the integral sawing guide to assist at least one of the sawing steps.

18. The method of claim 14 further comprising the steps of:
forming an integral sawing guide on the block-molded array; and
utilizing the integral sawing guide to assist at least one of the sawing steps;
wherein forming the integral sawing guide further comprises forming a raised ridge on the block-molded encapsulant.

19. The method of claim 14 further comprising the steps of:
forming an integral sawing guide on the block-molded array; and
utilizing the integral sawing guide to assist at least one of the sawing steps;
wherein forming the integral sawing guide further comprises forming a trench in the block-molded encapsulant.
